(19) United States
(12) Patent Application Publication
(10) Pub. No.: US 2026/0348811 A1
(43) Pub. Date: Nov. 5, 2026

(54) METHOD AND DEVICE FOR QUALITY-OPTIMISED AND OUTPUT-POTIMISED PRODUCTION OF DIELECTRIC ELASTOMER ACTUATORS

(71) Applicants: UNIVERSITÄT DES SAARLANDES, Saarbrücken (DE); ZEMA ZENTRUM FÜR MECHATRONIK UND AUTOMATISIERUNGSTECHNIK GEMEINNÜTZIGE GMBH, Saarbrücken (DE)

(72) Inventors: Bettina FASOLT, Saarbrücken (DE); Tobias WILLIAN, Neunkirchen/Kohlhof (DE); Aurel WELLER, Saarbrücken (DE); Stefan SEELECKE, Saarbrücken (DE)

(21) Appl. No.: 19/487,838

(22) PCT Filed: May 17, 2024
(86) PCT No.: PCT/EP2024/063804

§ 371 Date: Nov. 25, 2025

(30) Foreign Application Priority Data
May 27, 2023 (DE) 102023114038.8

(51) Int. Cl. G01N 3/38

(52) U.S. Cl. CPC G01N 3/38; G01N 2203/0051; G01N 2203/0062; G01N 2203/0641

(57) ABSTRACT

The invention relates to a method for manufacturing a dielectric elastomer actuator (10, 20) with an elastomer actuator film (1), comprising the steps of:
providing (S1, S2) the elastomer actuator film (1) comprising a dielectric elastic polymer layer (2) coated on one side with a conductive electrode layer (3);
testing (S3) a dielectric strength of the elastomer actuator film (1) by applying a test voltage in order to establish a field strength in the dielectric layer (2) that is below a breakdown field strength of the material of the dielectric layer;
locating (S4) at least one breakdown site (46) by means of an optical method; and
repairing (S5) the at least one located breakdown site (46) by applying a curable adhesive (45) followed by curing and/or by applying a repair film (44) to a side of the dielectric layer (2) opposite the electrode layer (3).

### TECHNICAL FIELD

The present invention relates to a method and a device for manufacturing dielectric elastomer actuators (DEA).

### BACKGROUND

Elastomer actuators, similar to piezoelectric actuators, enable a change in mechanical properties upon application of an electrical voltage. Such elastomer actuators are typically formed with a dielectric elastic polymer layer in the form of a film or the like—often based on a silicone polymer—which is arranged between two electrically conductive electrode surfaces disposed opposite one another. The electrode surfaces are likewise elastically deformable and may be formed, for example, with a polymer matrix into which electrically conductive particles are incorporated. Materials suitable for the electrically conductive particles include, for example, conductive carbon blacks, metal powders, or carbon nanotubes.

The elastomer actuators are driven with a voltage applied to the opposing electrode surfaces. The resulting electric field gives rise to an electrostatic attraction between the two electrode surfaces that acts on the elastic polymer layer, thereby deforming it and reducing its thickness, while simultaneously increasing its areal extension due to material displacement.

In recent years such elastomer actuators have come into focus because, due to energy-efficient and low-noise operation with sustainable materials—for example, materials that do not contain rare earths—they can replace conventional pneumatic, piezoelectric, or magnetically driven actuators.

To achieve a deformation significant for actuation purposes, it is necessary—given typical polymer layer thicknesses in the range of 20 to 200 μm—to apply voltages in the lower kilovolt range in order to reach electric field strengths on the order of 100 V/μm.

Due to thickness variations or embedded contaminants, local defects can arise during manufacture of such elastomer actuators. At such defect sites, an electrical breakdown can occur at typical operating voltages or the breakdown field strength may be reduced, such that the field strengths required for operation cannot be achieved.

A breakdown through the dielectric layer leads to a defect that results in a permanent electrical short circuit and thus prevents use for actuation and sensing purposes. In particular when such dielectric elastomer actuators are formed as multilayer systems from stacked elastomer actuator films, the yield of manufacturing such actuators can be significantly reduced, since a single defect can render the entire actuator unusable.

It is therefore an object of the present invention to provide a method for manufacturing an elastomer actuator film that enables early detection and repair of such defects in the early phase of manufacturing and that can be reliably utilized for further processing.

### SUMMARY OF THE INVENTION

This object is achieved by a method for producing a dielectric elastomer actuator film as defined in claim 1 and by a corresponding device as defined in the independent device claim.

Further embodiments are indicated in the depending subclaims.

According to a first aspect, a method for manufacturing a dielectric elastomer actuator with an elastomer actuator film is provided, comprising the steps of:
providing the elastomer actuator film comprising a dielectric elastic polymer layer coated on one side with a conductive electrode layer;
testing a dielectric strength of the elastomer actuator film by applying a test voltage in order to establish an electric field strength in the dielectric layer that is below a breakdown field strength of the material of the dielectric layer;
locating at least one breakdown site by means of an optical method; and
repairing the at least one located breakdown site by applying a curable adhesive and/or by applying a repair film to a side of the dielectric layer opposite the electrode layer.

As used herein, a “dielectric elastomer actuator film” denotes a dielectric elastic polymer layer that is coated on one or both sides with electrically conductive material, in particular formed as a film or other planar material. At least one electrode layer is applied to the dielectric layer. The elastomer actuator film is a planar structure having a thickness preferably between 20 μm and 500 μm, and more preferably between 20 μm and 50 μm. Suitable materials for the dielectric elastic polymer layer include polymers such as polyacrylates, polydimethylsiloxane (silicone), polyurethane, rubber materials, and thermoplastic elastomer gels.

The electrode layer can be formed by applying an initially liquid electrode material, for example by screen printing, dispensing, or the like. After application, the electrode material is cured or solidified so that it becomes firmly bonded to the dielectric layer.

These elastomer actuator films can be further processed into dielectric elastomer actuators (DEAs) in subsequent steps, either as a monolayer or by stacking, rolling, or folding to form multilayer systems or the like. The electrode material is preferably formed with electrically conductive particles embedded in a polymer. The electrically conductive particles may comprise conductive carbon black, graphite, CNTs (carbon nanotubes), metal particles or comparable substances, with a particle concentration above a percolation threshold.

Because further processing of a defective elastomer actuator film can lead to unusable actuator arrangements, it is necessary to check during or after manufacture of the film whether defects are present. Due to the materials used—e.g., elastic polymers such as silicones—at very small thicknesses, for example between 20 and 50 μm, defects are common that reduce the breakdown field strength.

For this reason, the above method initially provides the dielectric elastic polymer layer with the electrode layer on one side, in particular by applying and curing the electrode material, to form an elastomer actuator film.

The dielectric strength of the elastomer actuator film can be tested by placing the film over the area of a planar electrically conductive test electrode and applying a test voltage between the electrode layer and the test electrode, the test voltage being selected depending on the thickness of the dielectric layer. For example, the test voltage can be selected such that, for the given thickness of the dielectric layer, an electric field strength is established that is reduced by a safety margin—in particular between 10% and 40%, preferably between 20% and 30%—relative to the breakdown field strength of the material of the dielectric layer.

Alternatively or additionally, the test voltage can be selected such that the field strength in the dielectric layer is greater by a safety margin—particularly between 10% and 40%—than a specified field strength required for subsequent actuator operation.

The test voltage may be a DC voltage or an AC voltage in the frequency range from 0.1 Hz to 10 KHz.

Applying a test voltage between the test electrode and the applied electrode layer of the elastomer actuator film causes electrostatic attraction between the test electrode and the electrode layer, leading to areal contact between the uncoated surface of the film and the test electrode, and to establishment of an electric field across the dielectric layer.

The test voltage can be selected, as indicated above, such that the resulting field strength through the dielectric layer—when defect-free—is below the breakdown field strength, in particular approximately 60-90% of the breakdown field strength of the material. The test voltage can also be selected such that the field strength in the dielectric layer reaches the field strength necessary for actuation and provides the field strength within the dielectric layer for which a maximum dielectric strength is to be ensured. The magnitude of the field strength to be achieved by the test voltage depends on the actuator application in question.

By applying the test voltage, the elastomer actuator film is electrostatically attracted to the test electrode, such that the film lays against the electrode plate and any air in between is displaced. It can be provided that the voltage between the electrode layer and the test electrode is increased continuously to the test voltage, in particular in a ramped manner—for example, with a rise rate of 200 V/s to 1000 V/s. This achieves a reduction or avoidance of air inclusions between the test electrode and the film when the film is attracted.

At the same time, a current is measured. If an electrical breakdown occurs at a defect site, this can be detected by a flowing current whose magnitude is markedly greater than an expected current through the electrically insulating dielectric layer. If a current above a predetermined current threshold value—a so-called defect current—is detected, it is recognized that a defect is present.

It can be provided that during testing of the dielectric strength of the elastomer actuator film, the test voltage, after detection of a breakdown, remains applied for a predetermined period—for example between 5 ms and 100 ms—or for a predetermined charge flow that depends on the thickness of the film.

After the occurrence of a breakdown at a defect site, the breakdown site is initially very small in area but enlarges as the defect current persists. The voltage breakdown degrades or removes the material of the dielectric layer and a short circuit occurs, in which a current (defect current) flows from the upper electrode to the lower planar test electrode. As a result, the breakdown field strength is exceeded over an increasingly large region.

When the flow of a defect current is detected, the breakdown site is generally not yet visible. For this reason, the defect current is maintained for a predetermined time in order to ensure that the breakdown site enlarges and then becomes detectable by optical means—such as cameras—or optical detectors. For example, after detecting the defect current, the current flow can be maintained for a predetermined period, or it can be maintained until a predetermined amount of charge (time integral of the defect current) has passed through the polymer layer.

Furthermore, the locating of breakdown sites can be performed using optical methods, e.g., with an optical or thermal camera or by laser reflection measurement.

After the current flow is switched off, the elastomer actuator film is lifted from the test electrode and examined for visible breakdown sites by means of an optical detection system. A position of a breakdown site is identified and stored for a subsequent repair step.

In a subsequent step, a repair is carried out at the detected breakdown sites. The repair is generally performed on the side of the dielectric layer opposite the electrode layer.

The repair can comprise introducing an adhesive material that fills the breakdown site. When a preferably initially liquid adhesive is applied to the breakdown site, it is cured. The adhesive can be cured after application by UV light or by thermal treatment.

After curing, the adhesive should match—at least approximately—the chemical, electrical, and mechanical properties of the elastomer actuator film, or deviate by not more than 10% therefrom in each case. In addition, the adhesive should exhibit good adhesion to the film such that it does not detach from the material even at strains above 100%.

The adhesive may be applied, for example, with a dispensing machine, a syringe with a plunger, or a spatula.

Furthermore, to repair the located breakdown site, after application of the adhesive a repair film (or repair layer) of dielectric material can be applied such that it completely covers the breakdown site and, after curing of the adhesive, is firmly bonded to the dielectric layer. The repair film should have the same or very similar material properties as the elastomer actuator film, i.e., deviate by not more than 10% from the corresponding chemical, electrical, and mechanical properties of the film. The repair film corresponds to a repair piece having an area selected to be 10% to 1000%—preferably between 50% and 500%, more preferably between 100% and 200%—larger than the area of the breakdown site, such that sufficient overlap is provided in the surrounding edge region of the breakdown site for fixing the repair film to the dielectric layer.

If the breakdown site is larger—for example greater than 0.5 mm²—then, after application of the adhesive, a repair film can be applied to the region of the breakdown site and pressed uniformly, e.g., with a plunger or rod. The repair film may preferably have an identical material or a material with comparable properties to those of the polymer layer. By subsequently curing the adhesive, the repair film is permanently fastened on the elastic polymer layer.

In particular, the material of the repair film can correspond to the material of the dielectric layer and/or the thickness of the repair film can be equal to, less than, or greater than the thickness of the dielectric layer. The repair film is designed, with regard to its thickness and material, such that it increases the dielectric strength in the region of the breakdown site at least to the dielectric strength of the dielectric layer.

It can furthermore be provided that, to repair the located breakdown site, a self-adhesive or adhesion-fixing repair film is applied such that it completely covers the breakdown site and is firmly bonded to the dielectric layer.

It can be provided that, after repairing the at least one located breakdown site, the steps of testing the dielectric strength, locating a breakdown site, and repairing are repeated—preferably with the same test voltage—until no breakdown site is found for the previously selected field strength.

Subsequently, the elastomer actuator film can be further processed into a dielectric elastomer actuator. The further processing can comprise, for a single-layer actuator, applying a further electrode layer to the as yet uncoated surface of the dielectric layer, or forming a multilayer actuator, for example by stacking a plurality of elastomer actuator films coated on one or both sides, or by rolling two superposed elastomer actuator films coated on one side such that an electrode layer of a further section of a second film lies on the uncoated surface of a first film.

According to a further aspect, a device for manufacturing a dielectric elastomer actuator with an elastomer actuator film is provided, the device comprising:
a provision unit for providing the elastomer actuator film comprising a dielectric elastic polymer layer coated on one side with a conductive electrode layer;
a test apparatus configured to test a dielectric strength of the elastomer actuator film by applying a predetermined test voltage to establish a field strength in the dielectric layer below a breakdown field strength;
an inspection unit configured to locate at least one breakdown site by means of an optical method; and
a repair unit configured to repair the at least one located breakdown site by applying a curable adhesive and/or a repair film.

### BRIEF DESCRIPTION OF THE DRAWINGS

Embodiments are explained in greater detail below with reference to the accompanying drawings, in which:

FIG. 1 shows a cross-sectional view of an elastomer actuator film;

FIGS. 2a and 2b show cross-sectional views of exemplary elastomer actuators;

FIG. 3 shows a schematic illustration of a device for manufacturing elastomer actuators with a single-sided electrode layer;

FIG. 4 shows a flow diagram illustrating the method for manufacturing the elastomer actuator; and

FIG. 5 shows a cross-sectional view of a repair site.

### DETAILED DESCRIPTION OF EMBODIMENTS

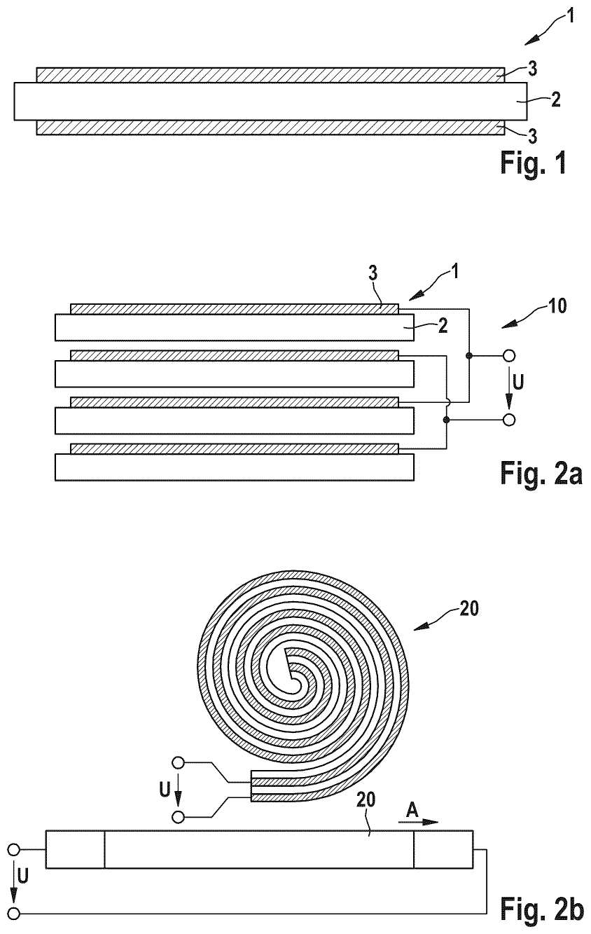

FIG. 1 shows a schematic illustration of an elastomer actuator film 1 having a dielectric elastic polymer layer 2 formed as a planar structure. The dielectric layer 2 has a thickness preferably between 20 μm and 200 μm, in particular between 20 μm and 50 μm. Rubber materials, polyurethanes, polyacrylates, or silicones can be used for the dielectric layer. The material of the dielectric layer 2 preferably has a dielectric strength of more than 100 V/μm.

An electrode layer 3 is applied on one or both sides (as shown) to the dielectric layer 2, the electrode layer being essentially electrically conductive. The electrode layer may comprise electrically conductive particles embedded in a polymer matrix with a particle concentration above the percolation threshold. The particles may include, in particular, conductive carbon black, graphite, CNTs (carbon nanotubes), and/or metal. The particles can be embedded in the polymer matrix, wherein the polymer preferably corresponds to or contains the material of the dielectric layer 2. In general, the material of the electrode layer 3 can have the same or a higher elasticity than that of the dielectric layer 2.

The material of the electrode layers 3 can be provided as a liquid or viscous material curable by suitable treatment. Using suitable application methods, the liquid or viscous material of the electrode layers can be applied, for example by screen printing—particularly by means of a printing roller. Subsequently, the applied material of the electrode layer is cured or dried by thermal treatment, UV irradiation, or otherwise, to form the electrode layer 3.

FIGS. 2a and 2b show cross-sectional views of possible elastomer actuators that can be formed with single-sided coated elastomer actuator films. FIG. 2a shows a multilayer actuator 10 formed by stacking a plurality of single-sided coated elastomer actuator films 1. With the exception of an outer film 1, the outer sides of the electrode layers 3 rest in each case against the uncoated surface of the dielectric layer 2 of a respective adjacent film 1. The electrode layers 3 are alternately assigned a polarity of a drive voltage U such that a voltage is applied across the dielectric layers to establish an electric field strength. The resulting electrostatic attraction compresses the dielectric layer 2 (reduces its thickness) and the areal extension of the multilayer actuator 10 increases.

FIG. 2b shows, as a further embodiment, a spiral elastomer actuator 20. Two superposed single-sided coated elastomer actuator films are rolled so that an alternating arrangement of electrode layers 3 and dielectric layers 2 is formed. By using two superposed films, two electrodes that can be placed at different electrical potentials are formed, allowing actuation by a drive voltage. When driven, the resulting electrostatic attraction causes a change in length in the axial direction A of the spiral arrangement.

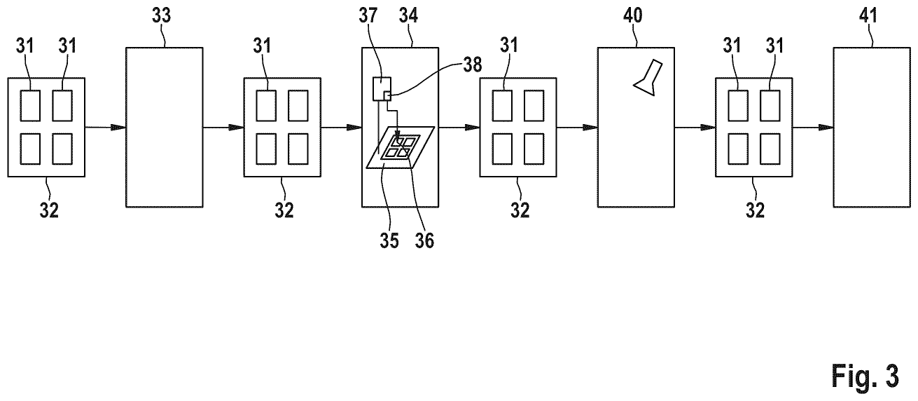

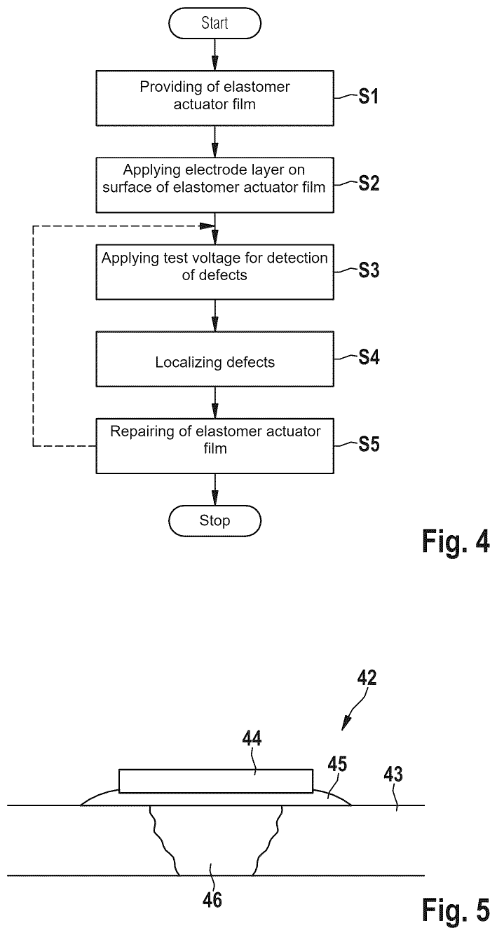

FIG. 3 shows a manufacturing device 30 for producing an elastomer actuator film 1 from a dielectric layer 2 and one or more electrode layers 3. The film serves to form an elastomer actuator, in particular as a multilayer actuator or a spiral actuator. The manufacturing method is described with reference to the device 30. A corresponding flow diagram is shown in FIG. 4.

In step S1, the manufacturing device 30 receives as starting material a dielectric elastic polymer layer in the form of a planar elastomer actuator film 31. The film 31 can be stretched and, for example, introduced under pre-tension into a holding frame 32.

In step S2, liquid or viscous electrode material is applied to one surface of the film by, for example, a screen printing device 33, and is cured by a suitable treatment step, such as thermal treatment or UV irradiation. The thus produced elastomer actuator films clamped in the holding frame 32 are then tested for dielectric strength in a test apparatus 34 with a plate-shaped test electrode 35.

For this purpose, in step S3 the holding frame with the manufactured film is placed with the uncoated surface on the electrically conductive planar test electrode 35 and, by suitable contacting—e.g., via a conductive plunger 36 adapted to the geometry of the electrode and that can in particular also be driven segment-wise—which is pressed onto the electrode layer on the top side, is subjected to a test voltage from a voltage source 37. The magnitude of the test voltage is selected such that, at nominal values—i.e., at the nominal thickness of the dielectric layer 2—an electric field strength is established between the test electrode 36 and the electrode layer 2 that corresponds to a suitably chosen test field strength and, for example, lies below the breakdown field strength by a tolerance amount of approximately 10-30%. For example, the test voltage may be selected such that an electric field strength of 100 V/um is established for the nominal thickness of the dielectric layer 2.

When the test voltage is applied, a current flow is simultaneously measured by a current meter 38. The current is monitored, and if it is determined that a predetermined current threshold value is exceeded, a defect and an electrical breakdown are inferred. The breakdown continues until the test voltage is switched off.

The test voltage can be applied as a ramped voltage increase with a rise rate between 50 V/s and 1000 V/s to cause the film to lay against the surface of the test electrode in such a way that as little air inclusion as possible remains between the film and the electrode.

The aim of the test apparatus 34 is to form a visible breakdown site at a defect that can be detected by optical means. For this purpose, after determination that the current threshold has been exceeded by the test current, the latter is further applied for a predetermined period, e.g., between 10 ms and 200 ms, so that it can be assumed that the breakdown site is visible. Alternatively, after detecting the breakdown, the predetermined period can also be defined by reaching a predetermined amount of charge passed since first detecting the breakdown.

Subsequently, the test voltage is switched off and, in step S4, the film is subjected to an optical inspection in an inspection unit 40. The optical inspection is performed on the uncoated surface of the actuator and can be carried out with cameras or by laser reflection measurements. Through the optical inspection, one or more breakdown sites are found. The position of the defect can be determined from the camera image or the laser reflection measurement and stored.

In a subsequent step S5, a repair of the dielectric layer on the side not coated with the electrode layer 3 is performed by means of a repair unit 41. First, it is checked whether the area of the breakdown site is greater than a predetermined breakdown area, for example 0.5 mm². If the area is smaller than the predetermined breakdown area, a repair can be carried out by applying an adhesive curable thermally, by UV light, or otherwise. For this purpose, the adhesive can be applied by means of a syringe or a spatula and then cured.

If the area of the breakdown site is greater than 0.5 mm², then in addition to applying the adhesive a repair film of a suitable material—for example, the material of the dielectric layer—can be applied. Such a repair site is shown, for example, in FIG. 5. A repair site 42 on an elastomer actuator film 43 is shown. The repair film 44 is placed on a layer of adhesive 45 and preferably has a thickness equal to or less than the thickness of the dielectric layer 2. After application of the repair film 44, curing of the adhesive 45 can be carried out as described above. The area of the repair film 44 is preferably selected such that it completely covers the breakdown site 46 and has an overlap area with the dielectric layer 2 around the breakdown site 46 that can amount to about 10% to 1000% of the area of the breakdown site.

Instead of the adhesive, a self-adhesive repair film or a repair film that is fixed to the surface of the dielectric layer 2 by adhesion can also be provided.

Subsequently, the thus formed elastomer actuator can be further processed in a manner known per se, i.e., either by applying an electrode layer to the second, still uncoated surface of the film 1, or by stacking or winding the single-sided coated film 1 to form a multilayer actuator or a spiral actuator.

The method can be carried out batch-wise as described above with one or more sections of the dielectric film arranged in the holding frames, in which these can be coated with the electrode material.

Alternatively, the method can also be executed on an endless belt of the dielectric layer material.

1. A method for manufacturing a dielectric elastomer actuator with an elastomer actuator film, comprising the steps of:
providing the elastomer actuator film comprising a dielectric elastic polymer layer coated on one side with a conductive electrode layer;
testing a dielectric strength of the elastomer actuator film by applying a test voltage in order to establish a field strength in the dielectric layer that is below a breakdown field strength of the material of the dielectric layer;
locating at least one breakdown site by means of an optical method; and
repairing the at least one located breakdown site by applying a curable adhesive followed by curing and/or by applying a repair film to a side of the dielectric layer opposite the electrode layer.

2. The method according to claim 1, wherein the dielectric strength of the elastomer actuator film is tested by placing the film over the area of a planar test electrode and applying a test voltage between the electrode layer and the test electrode, the test voltage being selected depending on the thickness of the dielectric layer such that a field strength is established in the dielectric layer that is reduced by a safety margin—particularly between 10% and 40%—relative to a breakdown field strength of the material of the dielectric layer.

3. The method according to claim 1, wherein, during testing of the dielectric strength of the elastomer actuator film, the test voltage remains applied after detection of a breakdown for a predetermined duration—particularly between 5 ms and 100 ms—or for a predetermined charge flow.

4. The method according to claim 1, wherein locating the breakdown sites is carried out by optical means, in particular by means of a camera or a laser reflection measurement.

5. The method according to claim 1, wherein, to repair the located breakdown site, adhesive is applied, in particular by means of a syringe, a plunger, or a spatula.

6. The method according to claim 5, wherein, to repair the located breakdown site, after application of the adhesive a repair film of dielectric material is applied such that it completely covers the breakdown site and, after curing of the adhesive, is firmly bonded to the dielectric layer.

7. The method according to claim 1, wherein, to repair the located breakdown site, a self-adhesive repair film or a repair film that is fixed by adhesion is applied such that it completely covers the breakdown site and is firmly bonded to the dielectric layer.

8. The method according to claim 7, wherein the material of the repair film corresponds to the material of the dielectric layer and/or the thickness of the repair film is equal to or less than the thickness of the dielectric layer.

9. The method according to claim 1, wherein providing the elastomer actuator film comprises single-sided or double-sided application of a conductive electrode material to a film of a dielectric layer.

10. The method according to claim 1, wherein the test voltage is provided as a DC voltage or as an AC voltage with a frequency in the range from 0.1 Hz to 10 kHz, wherein, in particular, when the test voltage is applied it is increased to the test voltage with a rise rate between 50 V/s and 1000 V/s.

11. The method according to claim 1, wherein, after repairing the at least one located breakdown site, the steps of testing the dielectric strength, locating a breakdown site, and repairing are repeated—preferably with the same test voltage—until no new breakdown site is found.

12. A device for manufacturing a dielectric elastomer actuator with an elastomer actuator film, the device comprising:
a provision unit for providing the elastomer actuator film comprising a dielectric elastic polymer layer coated on one side with a conductive electrode layer;
a test apparatus configured to test a dielectric strength of the elastomer actuator film by applying a test voltage to establish a field strength in the dielectric layer below a breakdown field strength of the material of the dielectric layer;
an inspection unit configured to locate at least one breakdown site by means of an optical method; and
a repair unit configured to repair the at least one located breakdown site by exclusively applying a curable adhesive followed by curing and/or by applying a repair film to a side of the dielectric layer opposite the electrode layer.
